(19) United States
(12) Patent Application Publication
(10) Pub. No.: US 2025/0176385 A1
(43) Pub. Date: May 29, 2025

(54) DISPLAY DEVICE AND ELECTRONIC DEVICE INCLUDING THE SAME

(71) Applicant: Samsung Display Co., Ltd., Yongin-Si (KR)

(72) Inventors: SUKYO JUNG, Yongin-si (KR); Minkyung Park, Yongin-si (KR); SEUNGWOO SUNG, Yongin-si (KR); YOUNG-SOO YOON, Yongin-si (KR); BONGWON LEE, Yongin-si (KR); WONSE LEE, Yongin-si (KR); DONGHYEON JANG, Yongin-si (KR); SEUNGHAN JO, Yongin-si (KR); MINHEE CHOI, Yongin-si (KR); SUNBAEK HONG, Yongin-si (KR)

(21) Appl. No.: 18/935,658

(22) Filed: Nov. 4, 2024

(30) Foreign Application Priority Data
Nov. 28, 2023 (KR) 10-2023-0167404

(51) Int. Cl. H10K 59/131; H10K 59/65

(52) U.S. Cl. CPC H10K 59/131; H10K 59/65

(57) ABSTRACT

A display device includes a substrate including a hole area, a display area, and a non-display, a first scan driver disposed adjacent to a first side of the display area, a second scan adjacent to a second side of the display area opposite to the first side of the display area, and to which a scan signal, different from a signal applied to the first scan driver, is applied, a first scan line including a first straight line along a first direction and a first bypass line bypassing along a boundary of the hole area, a second scan line including a second straight line extending along a direction opposite to the first direction and a second bypass line bypassing along the boundary of the hole area, and a data line extending along a second direction.

### CROSS-REFERENCE TO RELATED APPLICATION(S)

This application claims priority under 35 U.S.C. § 119 to Korean Patent Application No. 10-2023-0167404, filed on Nov. 28, 2023, which is hereby incorporated by reference for all purposes as if fully set forth herein.

### BACKGROUND

### 1. Field

Embodiments relate to a display device. More particularly, the embodiments relate to a display device with a hole.

### 2. Description of the Related Art

A display device may include a display area where an image is displayed and a non-display area located outside the display area. Pixels for displaying images and lines connected to the pixels may be arranged in the display area. Components such as driver units for driving pixels, camera modules, sensor modules, and the like may be disposed in the non-display area.

In order to reduce a dead space formed by the non-display area, a hole may be formed inside the display area. Components may be arranged on a rear surface of the display device to correspond to the hole, and the components may detect or recognize objects, users, and the like located in a front of the display device through the hole.

### SUMMARY

Embodiments provide a display device with a reduced dead space.

A display device according to an embodiment includes a substrate, a first scan driver, a second scan driver, a first scan line, a second scan line, and a data line. The substrate includes a hole area defining a hole, a display area adjacent to the hole area, and a non-display area adjacent to the display area. The first scan driver is disposed on the substrate and is adjacent to a first side of the display area. The second scan driver is disposed on the substrate, is adjacent to a second side of the display area opposite to the first side of the display area, and to which a scan signal, different from a scan signal applied to the first scan driver, is applied. The first scan line is electrically connected to the first scan driver, spaced apart from the second scan driver, and includes a first straight line extending from a portion connected to the first scan driver along a first direction and a first bypass line along a boundary of the hole area. The second scan line is electrically connected to the second scan driver, spaced apart from the first scan driver, and includes a second straight line extending from a portion connected to the second scan driver along a direction opposite to the first direction and a second bypass line bypassing along the boundary of the hole area. The data line is disposed on the substrate and extends along a second direction which intersects with the first direction.

In an embodiment, the first scan driver may be disconnected in an area adjacent to the second scan driver, and the second scan driver is disconnected in an area adjacent to the first scan driver.

In an embodiment, the display device may further include a third scan driver disposed on the substrate and adjacent to the first scan driver, a fourth scan driver disposed on the substrate and adjacent to the second scan driver, a third scan line electrically connected to the third scan driver and including a third straight line extending from a portion connected to the third scan driver along the first direction and a third bypass line along the boundary of the hole area, and a fourth scan line electrically connected to the fourth scan driver and including a fourth straight line extending from a portion connected to the fourth scan driver along the direction opposite to the first direction and a fourth bypass line along the boundary of the hole.

In an embodiment, the third scan line may be spaced apart from the second scan driver and the fourth scan driver, and the fourth scan line may be spaced apart from the first scan driver and third scan driver.

In an embodiment, the first straight line and the first bypass line may be integral, the second straight line and the second bypass line may be integral, the third straight line and the third bypass line may be integral, and the fourth straight line and the fourth bypass line may be integral.

In an embodiment, each of the first scan line, the second scan line, the third scan line, and the fourth scan line may be arranged alternatively along the second direction.

In an embodiment, each of the first scan line, the second scan line, the third scan line, and the fourth scan line may be arranged alternatively along a direction away from a center of the hole.

In an embodiment, the display device may further include a plurality of fifth scan drivers disposed on the first and second sides of the display area and spaced apart from each other in the first direction, and a plurality of fifth scan lines electrically connected to the fifth scan driver.

In an embodiment, the fifth scan drivers may be disconnected by the hole.

In an embodiment, different scan signals may be applied to the first scan driver, the second scan driver, the third scan driver, the fourth scan driver, and the fifth scan driver.

In an embodiment, the display device may further include a connection electrode disposed in the display area on the substrate and electrically connected to the data line around the hole area.

In an embodiment, an average distance from a center of the hole to the first scan line, the second scan line, the third scan line, and the fourth scan line may be smaller than an average distance from the center of the hole to the connection electrode.

In an embodiment, the data line may be disposed in a same layer with the connection layer.

In an embodiment, the data line may be disposed in a different layer from the connection layer.

A display device according to an embodiment includes a substrate, a first scan driver, a second scan driver, a first scan line, a second scan line, a data line, and a connection electrode. The substrate includes a hole area defining a hole, a display area adjacent to the hole area, and a non-display area adjacent to the display area. The first scan driver is disposed on the substrate and is adjacent to a first side of the display area. The second scan driver is disposed on the substrate, is adjacent to a second side of the display area opposite to the first side of the display area, and to which a scan signal, different from a signal applied to the first scan driver, is applied. The first scan line is electrically connected to the first scan driver, and extends from a portion connected to the first scan driver and is disconnected in an area adjacent to the second scan driver. The second scan line is electrically connected to the second scan driver, and extends from a portion connected to the second scan driver and is disconnected in an area adjacent to the first scan driver. The data line is disposed on the first scan line and the second scan line and extends along a second direction intersecting with the first direction. The connection electrode is disposed on the first scan line and the second scan line, and is electrically connected to the data line around the hole area.

In an embodiment, the first scan line may include a first straight line parallel to the first direction and a first bypass line bypassing a boundary of the hole area, and the second scan line may include a second straight line parallel to the first direction and a second bypass line bypassing the boundary of the hole area.

In an embodiment the first straight line and the second straight line may be arranged alternatively along the second direction, and the first bypass line and the second bypass line may be arranged alternatively along a direction away from a center of the hole.

In an embodiment the first straight line and the first bypass line may be integral, and the second straight line and the second bypass line may be integral.

In an embodiment different scan signals may be applied to the first scan driver and the second scan driver.

In an embodiment the data line may be disposed in a same layer with the connection electrode.

In a display device according to embodiments of the present disclosure, the display device may include a substrate including a hole area in which at least one hole is defined, and a display area adjacent to the hole area, first, second, third, and fourth scan lines disposed on the substrate, a data lines disconnected by the hole area, and a connection electrode which electrically connects the data lines disconnected by the hole area. Accordingly, the first, second, third, and fourth scan drivers may be one-side driving scan drivers by being disposed adjacent to one side of the display area, and the first, second, third, and fourth scan drivers electrically connected to the first, second, third, and fourth scan drivers respectively may include first, second, third, and fourth bypass lines. Accordingly, a dead space of the display device may be reduced, and a size of the display area may increase.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating a display device according to an embodiment of present disclosure.

FIG. 2 is a circuit diagram illustrating a pixel of FIG. 1.

FIG. 3 is an enlarged plan view illustrating an area A of FIG. 1.

FIG. 4 is a cross-sectional view illustrating a cross-section taken along line I-I′ of FIG. 3.

FIG. 5 is a cross-sectional view illustrating a cross-section taken along line II-II′ of FIG. 3.

FIG. 6 is a plan view illustrating a display panel of FIG. 1.

FIG. 7 is a plan view illustrating an example of lines passing a hole area of FIG. 6 and scan drivers connected to the lines.

FIG. 8 is a cross-sectional view illustrating a cross-section taken along line III-III′ of FIG. 7.

FIG. 9 is a cross-sectional view illustrating an example of a cross-section taken along line IV-IV′ of FIG. 7.

FIG. 10 is a cross-sectional view illustrating another example of a cross-section taken along line IV-IV′ of FIG. 7.

FIG. 11 is a plan view illustrating another example of lines passing a hole area of FIG. 6 and scan drivers connected to the lines.

FIG. 12 is a cross-sectional view illustrating a cross-section taken along line V-V′ of FIG. 11.

FIG. 13 is a block diagram illustrating an electronic device according to an embodiment.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

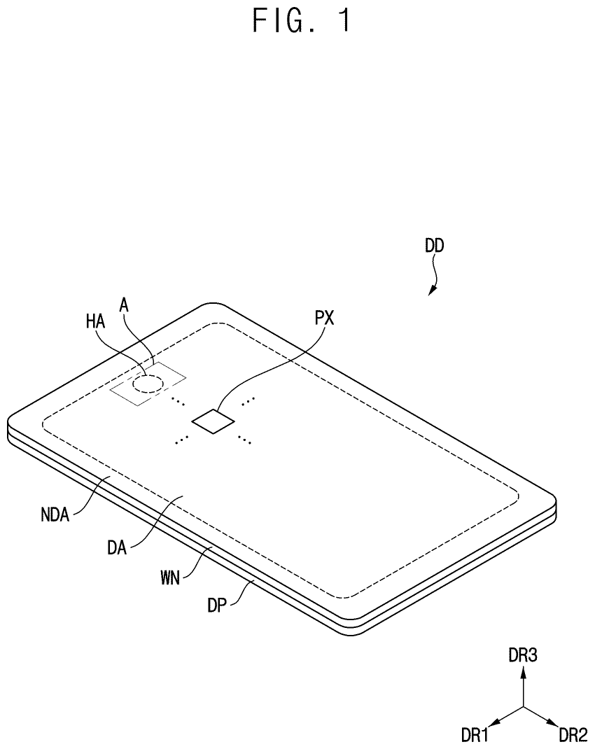

FIG. 1 is a perspective view illustrating a display device DD according to an embodiment of present disclosure.

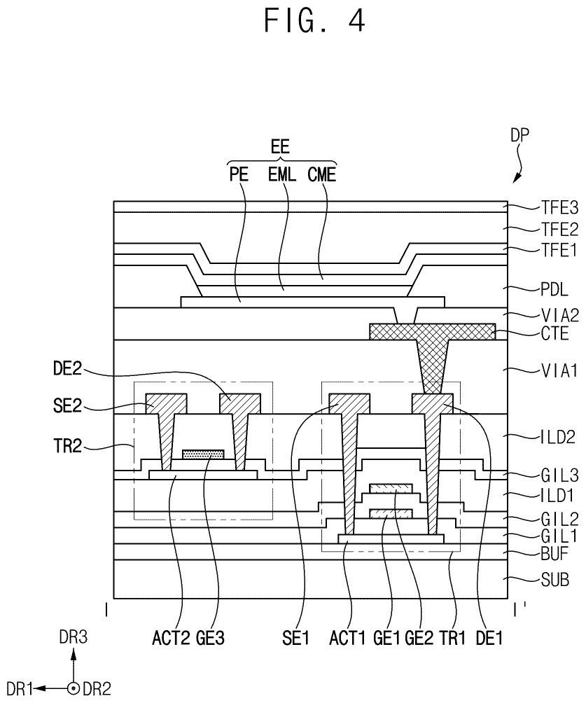

Referring to FIG. 1, the display device DD according to an embodiment of present disclosure may include a display panel DP and a window layer WN. The display panel DP may include components to drive the display device DD. This will be explained in detail with reference to FIGS. 4 to 6.

The window layer WN is disposed on the display panel DP. The window layer WN may protect the display panel DP from an external impact. The window layer WN may be an ultra-thin glass (UTG). For example, the window layer WN may include a soda-lime glass, an alkali aluminosilicate glass, a borosilicate glass, a lithium aluminosilicate glass, and the like. These may be used in alone or in combination with each other. However, the window layer WN of the present disclosure may not be limited to this, and the window layer WN may include various materials such as a plastic.

In this specification a plane may be defined by a first direction DR1 and a second direction DR2 intersecting with the first direction DR1. For example, the first direction DR1 may be perpendicular to the second direction DR2. In addition, a third direction DR3 may be perpendicular to the plane.

The display device DD may include a display area DA, a non-display area NDA, and a hole area HA. The display area DA may be defined as an area which displays images by generating a light or adjusting a penetration rate of a light provided from an outside light source. At least one pixel PX may be disposed in the display area DA. The pixel may emit a light.

A plurality of pixels PX may be arranged in a matrix form. For example, the plurality of the pixels PX may be arranged along the first direction DR1 and the second direction DR2. In addition, the pixel PX may include a plurality of sub-pixels which emit light of different colors. For example, the sub-pixels may include a red sub-pixel which emits a red light, a green sub-pixel which emits a green light and a blue sub-pixel which emits a blue light.

The non-display area NDA may be defined as an area which does not display images. The non-display area NDA may be adjacent to the display area DA. For example, the non-display area NDA may surround at least a portion of the display area DA.

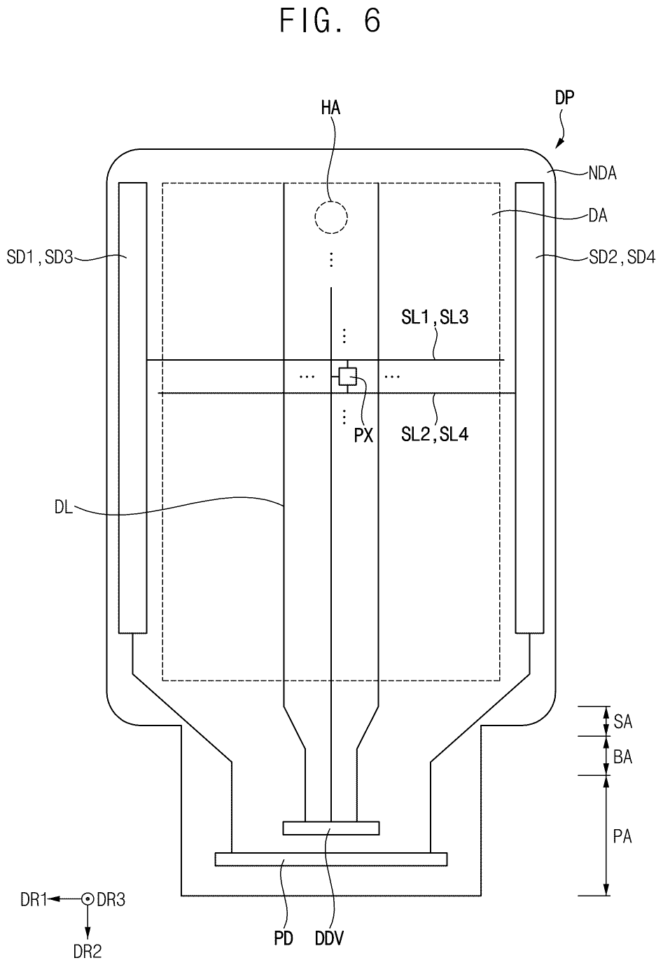

A driver may be disposed in the non-display area NDA. For example, the driver may be a component to drive the pixel PX. The driver may include a data driver (e.g., a data driver DDV of FIG. 6), a scan driver (e.g., a first scan driver SD1 and a second scan driver SD2 of FIG. 6), a pad portion (e.g., a pad portion PD of FIG. 6), and a timing controller. The pixel may emit lights based on a signal from the driver.

The hole area HA may be disposed in the display area DA. In an embodiment, the hole area HA may be disposed in an upper center of the display area DA. In an embodiment, the hole area HA may be disposed in an upper left corner of the display area DA. In an embodiment, the hole area HA may be disposed in an upper right corner of the display area DA. However, embodiments of the present disclosure may not be limited this.

In an embodiment, the hole area HA may have a circular shape in a plan view. In an embodiment, the hole area HA may have a different shape from the circular shape in a plan view. For example, the hole area HA may have a polygonal shape in a plan view. However, embodiments of the present disclosure may not be limited this.

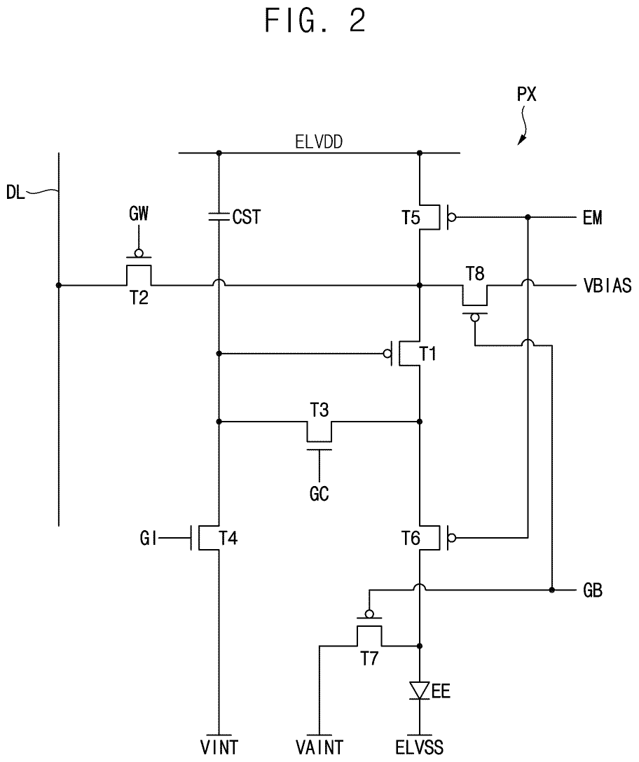

FIG. 2 is a circuit diagram illustrating a pixel of FIG. 1.

Referring to FIG. 2, the pixel PX may include a first transistor T1, a second transistor T2, a third transistor T3, a fourth transistor T4, a fifth transistor T5, a sixth transistor T6, a seventh transistor T7, an eighth transistor T8, a storage capacitor CST, and a light-emitting element EE.

An input terminal of the first transistor T1 may be connected to a data line DL. For example, the first transistor T1 may apply a data voltage from the data line DL through the input terminal and generate a driving current corresponding to the data voltage.

The output terminal of the first transistor T1 may be connected to the light-emitting element EE. For example, the first transistor T1 may apply the driving current to the light-emitting element EE. A gate terminal of the first transistor T1 may be connected to the storage capacitor CST.

An input terminal of the second transistor T2 may be connected to the data line DL. An output terminal of the second transistor T2 may be connected to the input terminal of the first transistor T1. A gate write signal GW may be applied to a gate terminal of the second transistor T2.

Accordingly, the second transistor T2 may be turned on by the gate write signal GW. During an interval when the second transistor T2 is turned on, the second transistor T2 may apply the data voltage to the first transistor T1.

An input terminal of the third transistor T3 may be connected to the output terminal of the first transistor T1. An output terminal of the third transistor T3 may be connected to the gate terminal of the first transistor T1. The gate compensate signal GC may be applied to a gate terminal of the third transistor T3.

Accordingly, the third transistor T3 may be turned on by the gate compensate signal GC. During an interval when the third transistor T3 is turned on, the third transistor T3 may compensate a threshold voltage as the third transistor T3 diode-connects the first transistor T1.

A first initialization voltage VINT may be applied to an input terminal of the fourth transistor T4. An output terminal of the fourth transistor T4 may be connected to the gate terminal of the first transistor T1. A first gate initialization signal GI may be applied to a gate terminal of the fourth transistor T4.

Accordingly, the fourth transistor T4 may turned on by the first gate initialization signal GI. During an interval when the fourth transistor T4 is turned on, the fourth transistor T4 may apply the first initialization voltage VINT to the gate terminal of the first transistor T1.

The first power voltage ELVDD may be applied to an input terminal of the fifth transistor T5. An output terminal of the fifth transistor T5 may be connected to the input terminal of the first transistor T1. A light emission control signal EM may be applied to a gate terminal of the fifth transistor T5.

Accordingly, the fifth transistor T5 may be turned on by the light emission control signal EM. During an interval when the fifth transistor T5 is turned on, the fifth transistor T5 may apply the first power voltage ELVDD to the first transistor T1.

In an embodiment, the first power voltage ELVDD and a second power voltage ELVSS applied to the light-emitting element EE may be constant voltages. The first power voltage ELVDD and the second power voltage ELVSS may have different voltage levels each other.

An input terminal of the sixth transistor T6 may be connected to the output terminal of the first transistor T1. An output terminal of the sixth transistor T6 may be connected to the light-emitting element EE. The light emission control signal EM may be applied to a gate terminal of the sixth transistor.

Accordingly, the sixth transistor T6 may be turned on by the light emission control signal EM. During an interval when the sixth transistor T6 is turned on, the sixth transistor T6 may apply the driving current to the light-emitting element EE.

A second initialization voltage VAINT may be applied to an input terminal of the seventh transistor T7. An output terminal of the seventh transistor T7 may be connected to the light-emitting element EE. A second gate initialization signal GB may be applied to a gate terminal of the seventh transistor T7.

Accordingly, the seventh transistor T7 may be turned on by the second gate initialization signal GB. During an interval when the seventh transistor T7 is turned on, the seventh transistor T7 may apply the second initialization voltage VAINT to the light-emitting element EE.

A bias voltage VBIAS may be applied to an input terminal of the eighth transistor T8. An output terminal of the eighth transistor T8 may be connected to the input terminal of the first transistor T1. The second gate initialization signal GB may be applied to the gate terminal of the eighth transistor T8.

Accordingly, the eighth transistor T8 may be turned on by the second gate initialization signal GB. During an interval when the eighth transistor T8 is turned on, the eighth transistor T8 may apply the bias voltage VBIAS to the first transistor T1.

A first terminal of the storage capacitor CST may be connected to the gate terminal of the first transistor T1. The first power voltage ELVDD may be applied to a second terminal of the storage capacitor CST, which is opposite to the first terminal.

The storage capacitor CST may be used to maintain a voltage level of a gate electrode which is the gate terminal of the first transistor T1 during an inactive interval of the gate write signal GW.

In FIG. 2, the first transistor T1, the second transistor T2, the fifth transistor T5, the sixth transistor T6, the seventh transistor T7, and the eighth transistor T8 are illustrated as PMOS transistors, and the third transistor T3 and the fourth transistor T4 are illustrated as NMOS transistors, however a type of each of the first transistor T1, the second transistor T2, the third transistor T3, the fourth transistor T4, the fifth transistor T5, the sixth transistor T6, the seventh transistor T7, and the eighth transistor T8 may not be limited to this.

In FIG. 2, the pixel PX shown as including eight transistors and one capacitor, however, embodiments of the present disclosure may not be limited this For example, the pixel PX may include 2 to 7 or 9 or more transistors and two or more capacitors.

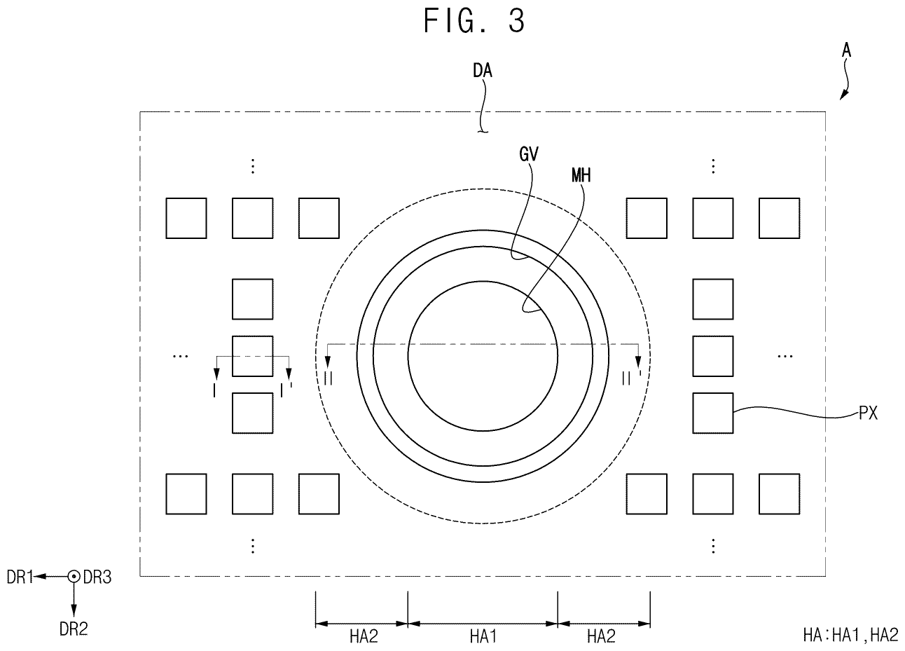

FIG. 3 is an enlarged plan view illustrating an area A of FIG. 1. FIG. 4 is a cross-sectional view illustrating a cross-section taken along line I-I′ of FIG. 3.

Referring to FIGS. 3 and 4, the hole area HA may include a first hole area HA1 and a second hole area HA2. For example, the second hole area HA2 may surround the first hole area HA1. The display area DA may surround the second hole area HA2.

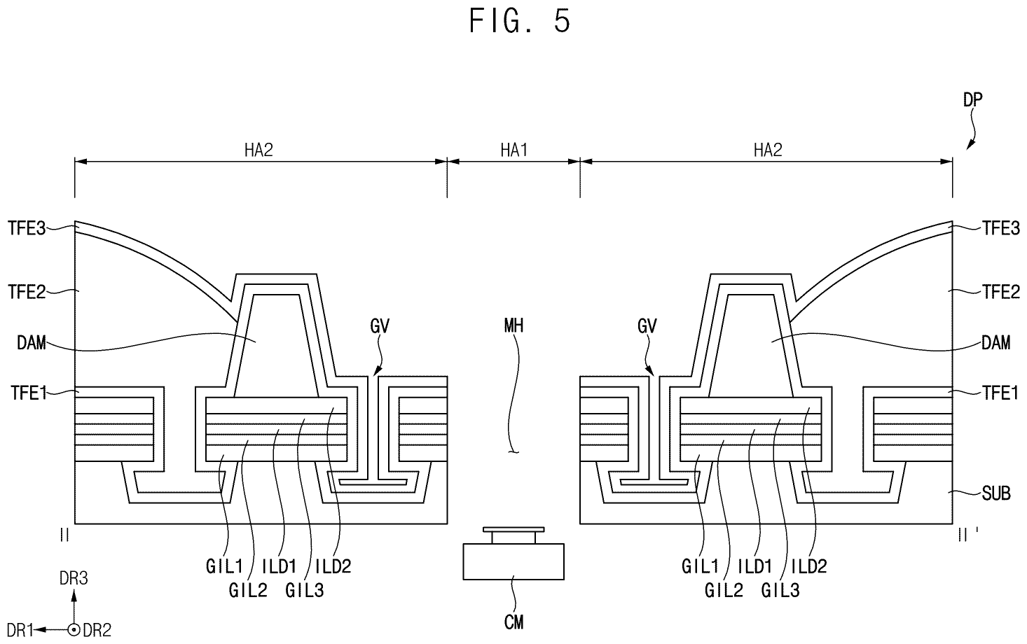

At least one hole MH may defined in the first hole area HA1. At least one groove pattern GV may be defined in the second hole area HA2. Details on this will be described later with reference to FIG. 5.

The pixel PX may be disposed in the display area DA. For example, the pixel PX may be disposed in the display area DA adjacent to a boundary of the second hole area HA2. That is, the hole area HA may be an area in which the pixel PX is not disposed.

The plurality of pixels PX may be arranged regularly in a plane. For example, the pixels PX may have a pixel arrangement of pentile®. However, the embodiments of present disclosure may not be limited to this.

The display panel DP may include a substrate SUB, a buffer layer BUF, a first active pattern ACT1, a first gate insulation layer GIL1, a first gate electrode GE1, a second gate insulation layer GIL2, a second gate electrode GE2, a first interlayer insulation layer ILD1, a second active pattern ACT2, a third gate insulation layer GIL3, a third gate electrode GE3, a second interlayer insulation layer ILD2, a first source electrode SE1, a first drain electrode DE1, a second source electrode SE2, a second drain electrode DE2, a first via insulation layer VIA1, a contact electrode CTE, a second via insulation layer VIA2, a pixel electrode PE, a light-emitting layer EML, a pixel define layer PDL, a common electrode CME, a first encapsulation layer TFE1, a second encapsulation layer TFE2, and a third encapsulation layer TFE3.

The display panel DP in the hole area HA may omit some of components including metal layers among components of the display panel DP in the display area DA.

As described above reference with FIG. 1, the display area DD may include the display area DA and the hole area HA. As the display device DD includes the display area DA and the hole area HA, the substrate SUB may include the display area DA and the hole area HA.

The substrate SUB may include a transparent material or an opaque material. The substrate SUB may include a transparent resin substrate. For example, the transparent resin may include a polyimide substrate. In this case, the polyimide substrate may include a first organic layer, a first barrier layer, a second organic layer, and the like. In another example, the substrate SUB may include a quartz substrate, a synthetic quartz substrate, a calcium fluoride substrate, a fluorine-doped quartz substrate, a soda lime glass substrate, a non-alkali glass substrate, and the like. These may be used in alone or in combination with each other.

The buffer layer BUF may disposed on the substrate SUB. The buffer layer BUF may prevent metal atoms or impurities from diffusing from the substrate SUB to the first and second transistors TR1 and TR2. In addition, the buffer layer BUF may improve a flatness of a surface of the substrate SUB when the surface of the substrate SUB is not uniform. For example, the buffer layer BUF may include an inorganic material such as a silicon oxide, a silicon nitride, a silicon oxynitride, and the like. These may be used in alone or in combination with each other.

The first active pattern ACT1 may disposed on the buffer layer BUF. In an embodiment, the first active pattern ACT1 may include an inorganic semiconductor such as an amorphous silicon, a polycrystalline silicon. For example, the first active pattern ACT1 may include a first source area, a first drain area, and a first channel area located between the first source area and the first drain area.

The first gate insulation layer GIL1 may disposed on the buffer layer BUF. The first gate insulation layer GIL1 may cover the first active pattern ACT1 and may be disposed with a uniform thickness along a profile of the first active pattern ACT1. In another example, the first gate insulation layer GIL1 may sufficiently cover the first active pattern ACT1 and may have a substantially flat upper surface without creating a step around the first active pattern ACT1. For example, the first gate insulation layer GIL1 may include an inorganic material such as a silicon oxide, a silicon nitride, a silicon carbide, a silicon oxynitride, a silicon oxycarbide, and the like. These may be used in alone or in combination with each other.

The first gate electrode GE1 may disposed on the first gate insulation layer GIL1. The first gate electrode GE1 may overlap the first channel area of the first active pattern ACT1. The first gate electrode GE1 may include a metal, an alloy, a metal nitride, a conductive metal oxide, a transparent conductive material, and the like. Examples of the metal may include silver, a molybdenum, an aluminum, a tungsten, a copper, a nickel, a chromium, a titanium, a tantalum, a platinum, a scandium, and the like. Examples of the conductive metal oxide may include an indium tin oxide and an indium zinc oxide. In addition, examples of the metal nitride may include an aluminum nitride, a tungsten nitride, and a chromium nitride. These may be used in alone or in combination with each other.

The second gate insulation layer GIL2 may be disposed on the first gate insulation layer GIL1. The second gate insulation layer GIL2 may cover the first gate electrode GE1, and may be disposed with a uniform thickness along a profile of the first gate electrode GE1. In another example, the second gate insulation layer GIL2 may sufficiently cover the first gate electrode GE1, and may have a substantially flat upper surface without creating a step around the first gate electrode GE1. For example, the second gate insulation layer GIL2 may include an inorganic material such as a silicon oxide, a silicon nitride, a silicon carbide, a silicon oxynitride, a silicon oxycarbide, and the like. These may be used in alone or in combination with each other.

The second gate electrode GE2 may disposed on the second gate insulation layer GIL2. The second gate electrode GE2 may overlap the first gate electrode GE1. For example, the second gate electrode may include a metal, an alloy, a metal nitride, a conductive metal oxide, a transparent conductive material, and the like. These may be used in alone or in combination with each other.

The first interlayer insulation layer ILD1 may disposed on the second gate insulation layer GIL2. The first interlay insulation layer ILD1 may cover the second gate electrode GE2, and may disposed with a uniform thickness along a profile of the second gate electrode GE2. In another example, the first interlayer insulation layer ILD1 may sufficiently cover the second gate electrode GE2, and have a substantially flat upper surface without creating a step around the second gate electrode GE2. For example, the first interlayer insulation layer ILD1 may include an inorganic material such as a silicon oxide, a silicon nitride, a silicon carbide, a silicon oxynitride, a silicon oxycarbide, and the like. These may be used in alone or in combination with each other.

The second active pattern ACT2 may disposed on the first interlayer insulation layer ILD1. In an embodiment, the second active pattern ACT2 may include a metal oxide semiconductor. For example, the second active pattern ACT2 may include a second source area, a second drain area, and a second channel area located between the second source area and the second drain area.

The metal oxide semiconductor may include a binary compound (ABₓ), a ternary compound (ABₓC_{y}), a quaternary compound (ABₓC_{y}D_{z}), and the like including an indium, a zinc, a gallium, a tin, a titanium, an aluminum, a hafnium, a zirconium, a magnesium, and the like. For example, the metal oxide semiconductor may include a zinc oxide (ZnOₓ), a gallium oxide (GaOₓ), a atin oxide (SnOₓ), an indium oxide (InOₓ), an indium gallium oxide (IGO), an indium zinc oxide (IZO), an indium tin oxide. (ITO), an indium zinc tin oxide (IZTO), an indium gallium zinc oxide (IGZO), and the like. These may be used in alone or in combination with each other.

The third gate insulation layer GIL3 may disposed on the first interlayer insulation layer ILD1. The third gate insulation layer GIL3 may cover the second active pattern ACT2, and may be disposed with a uniform thickness along a profile of the second active pattern ACT2. In another example, the third gate insulation layer GIL3 may sufficiently cover the second active pattern ACT2, and have a substantially flat upper surface without creating a step around the second active pattern ACT2. For example, the third gate insulation layer GIL3 may include an inorganic material such as a silicon oxide, a silicon nitride, a silicon oxynitride, and the like.

The third gate electrode GE3 may disposed on the third gate insulation layer GIL3. The third gate electrode GE3 may overlap the second channel area. For example, the third gate electrode GE3 may include a metal, an alloy, a metal nitride, a conductive metal oxide, a transparent conductive material, and the like. These may be used in alone or in combination with each other.

The second interlayer insulation layer ILD2 may disposed on the third gate insulation layer GIL3. The second interlayer insulation layer ILD2 may cover the third gate insulation layer GIL3, and may be disposed with a uniform thickness along a profile of the third gate insulation layer GIL3. In another example, the second interlayer insulation layer ILD2 may sufficiently cover the third gate insulation layer GIL3, and have a substantially flat upper surface without creating a step around the third gate insulation layer GIL3. For example, the second interlayer insulation layer ILD2 may include an inorganic material such as a silicon oxide, a silicon nitride, a silicon oxynitride, and the like.

The first source electrode and the first drain electrode SE1 and DE1 may be disposed on the second interlayer insulation layer ILD2. The first source electrode SE1 may connect to the first source area of the first active pattern ACT1 through a contact hole penetrating the first gate insulation layer GIL1, the second gate insulation layer GIL2, the first interlayer insulation layer ILD1, the third gate insulation GIL3, and the second interlayer insulation layer ILD2. The first drain electrode DE1 may connect to the first drain area of the first active pattern ACT1 through a contact hole penetrating the first gate insulation layer GIL1, the second gate insulation layer GIL2, the first interlayer insulation layer ILD1, the third gate insulation GIL3, and the second interlayer insulation layer ILD2. For example, the first source electrode and the first drain electrode SE1 and DE1 may include a metal, an alloy, a metal nitride, a conductive metal oxide, a transparent conductive material, and the like. These may be used in alone or in combination with each other.

The second source electrode and the second drain electrode SE2 and DE2 may be disposed on the second interlayer insulation layer ILD2. The second source electrode SE2 may connect to the second source area of the second active pattern ACT2 through a contact hole penetrating the third gate insulation GIL3 and the second interlayer insulation layer ILD2. The second drain electrode DE2 may connect to the second drain area of the second active pattern ACT2 through a contact hole penetrating the third gate insulation GIL3 and the second interlayer insulation layer ILD2. The second source electrode and the second drain electrode SE2 and DE2 may include same materials and be disposed in a same layer as the first source electrode and the first drain electrode SE1 and DE1, respectively.

Accordingly, the first active pattern ACT1, the first gate electrode GE1, the second gate electrode GE2, the first source electrode SE1, and the first drain electrode DE1 may form the first transistor TR1. The second active pattern ACT2, the second gate electrode GE2, the third gate electrode GE3, the second source electrode SE2, and the second drain electrode DE2 may form the second transistor TR2.

The first via insulation layer VIA1 may be disposed on the second interlayer insulation layer ILD2. The first via insulation layer VIA1 may sufficiently cover the first source electrode SE1, the first drain electrode DE1, the second source electrode SE2, and the second drain electrode DE2. The first via insulation layer VIA1 may include an organic material such as a polyimide resin, a polyamide resin, a siloxane resin, an epoxy resin, and the like. These may be used in alone or in combination with each other.

The contact electrode CTE may disposed on the first via insulation layer VIA1. The contact electrode CTE may connect the first drain electrode DE1 through a contact hole penetrating via insulation layer VIA1. Accordingly, the contact electrode CTE may connect electrically the first transistor T1 and the light-emitting element EE. For example, the contact electrode may include a metal, an alloy, a metal nitride, a conductive metal oxide, a transparent conductive material, and the like. These may be used in alone or in combination with each other.

The second via insulation layer VIA2 may be disposed on the first via insulation layer VIA1. The second via insulation layer VIA2 may cover the contact electrode CTE. The second via insulation layer VIA2 may have a substantially flat upper surface. The second via insulation layer VIA2 may include an organic material. For example, the second via insulation layer VIA2 may include an organic material such as a polyimide resin, a polyamide resin, a siloxane resin, an epoxy resin, and the like. These may be used in alone or in combination with each other.

The pixel electrode PE may disposed on the second via insulation layer VIA2. The pixel electrode PE may contact the second drain electrode DE2 through a contact hole penetrating the second via insulation layer VIA2. The pixel electrode PE may include a metal, an alloy, a conductive metal oxide, a conductive metal nitride, a transparent conductive material, and the like. These may be used in alone or in combination with each other. For example, the pixel electrode PE may include a silver and an indium tin oxide.

The pixel define layer PDL may be disposed on the second via insulation layer VIA2. The pixel define layer PDL may partially cover the pixel electrode PE. In addition, an opening that extends to and exposes at least a portion of the pixel electrode PE may be defined in the pixel define layer PDL. For example, the opening of the pixel define layer PDL may extend to and expose a central portion of the pixel electrode PE, and the pixel define layer PDL may cover edges of the pixel electrode PE.

The pixel define layer PDL may include an inorganic material or an organic material. In an embodiment, the pixel define layer PDL may include an organic material such as an epoxy resin, a siloxane resin, and the like. These may be used in alone or in combination with each other. In an embodiment, the pixel define layer PDL may further include a light blocking material containing black pigment, black dye, and the like.

The light-emitting layer EML may be disposed on the pixel define layer PDL. The light-emitting layer EML may be disposed on the pixel electrode PE exposed by the opening of the pixel define layer PDL. The light-emitting layer EML may include an organic light emitting material. The organic light emitting material may include a low molecular weight organic compound or a high molecular weight organic compound. However, the present disclosure may not be limited to this, and the light-emitting layer EML may include materials such as quantum dots.

The common electrode CME may be disposed on the light-emitting layer EML. The common electrode CME may include a metal, an alloy, a conductive metal oxide, a conductive metal nitride, a transparent conductive material, and the like. For example, the common electrode CME may include an aluminum, a platinum, a silver, a magnesium, a gold, a chromium, a tungsten, a titanium, and the like. These may be used in alone or in combination with each other.

The pixel electrode PE, the light-emitting layer EML, and the common electrode CME may form the light-emitting element EE.

The first encapsulation layer TFE1 may be disposed on the common electrode CME. The first encapsulation layer TFE1 may cover the light-emitting element EE. The first encapsulation layer TFE1 may have a substantially uniform thickness along a profile of the common electrode CME. The first encapsulation layer TFE1 may include a silicon oxide, a silicon nitride, a silicon oxynitride, and the like. These may be used in alone or in combination with each other.

The second encapsulation layer TFE2 may be disposed on the first encapsulation layer TFE1. The second encapsulation layer TFE2 may not create a step around the first encapsulation layer TFE1 and may have a substantially flat upper surface. The second encapsulation layer TFE2 may include an organic material such as a polyacrylate.

The third encapsulation layer TFE3 may be disposed on the second encapsulation layer TFE2. The third encapsulation layer TFE3 may have a substantially uniform thickness and a substantially flat upper surface. The third encapsulation layer TFE3 may include a silicon oxide, a silicon nitride, a silicon oxynitride, and the like. These may be used in alone or in combination with each other.

The first, second, and third encapsulation layers TFE1, TFE2, and TFE3 may seal the display area DA and protect the light-emitting device EE from external impurities.

FIG. 5 is a cross-sectional view illustrating a cross-section taken along line II-II′ of FIG. 3.

Hereinafter, configurations that overlap with those described with reference to FIG. 4 will be omitted or simplified.

Referring to FIG. 5, at least one of the hole MH penetrating the first gate insulation layer GIL1, the second gate insulation layer GIL2, the first interlayer insulation layer ILD1, the third gate insulation layer GIL3, the second interlayer insulation layer ILD2, the first encapsulation layer TFE1, the second encapsulation layer TFE2, and the third encapsulation layer TFE3 may be defined in the first hole area HA1. The first hole area HA1 is an area where a light is transmitted through the hole MH. A component CM may be disposed under the substrate SUB corresponding to the first hole area HA1. The component CM may receive the light passing through the first hole area HA1.

In an embodiment, examples of the component CM include a camera module, a face recognition sensor module, a pupil recognition sensor module, an acceleration sensor module, a proximity sensor module, an infrared sensor module, and an illumination sensor module. The camera module may be a module that captures (or recognizes) an image of an object located in front of the display device. The facial recognition sensor module may be a module that detects the user's face. The pupil recognition sensor module may be a module that detects the user's pupils. The acceleration sensor module and the geomagnetic sensor module may be modules that determine movement of the display device. The proximity sensor module and the infrared sensor module may be modules that detect proximity to the front of the display device. The illuminance sensor module may be a module that measures the degree of external brightness.

At least one of the groove pattern GV having a shape in which a portion of the substrate SUB is recessed shape may be defined in the second hole area HA2. The groove pattern GV may be defined in a portion of the substrate SUB where the first gate insulation layer GIL1, the second gate insulation layer GIL2, the first interlayer insulation layer ILD1, the third gate insulation layer GIL3, and the second interlayer insulation layer ILD2 are removed. The first encapsulation layer TFE1 and the third encapsulation layer TFE3 may extend along a profile of the groove pattern GV. Accordingly, inflow paths of moisture and oxygen flowing through the first encapsulation layer TFE1 and the third encapsulation layer TFE3 may be extended. In addition, a propagation path of the crack transmitted through the first encapsulation layer TFE1 and the third encapsulation layer TFE3 may be extended. Accordingly, a reliability and a stability of the display device (e.g., the display device DD of FIG. 1) may be improved.

The first gate insulation layer GIL1, the second gate insulation layer GIL2, the first interlayer insulation layer ILD1, the third gate insulation layer GIL3, and the second interlayer insulation layer ILD2 may be disposed on a portion of the substrate SUB adjacent to the groove pattern GV. Specifically, the portion of the substrate SUB adjacent to the groove pattern GV may have a under-cut shape with the first gate insulation layer GIL1, the second gate insulation layer GIL2, the first interlayer insulation layer ILD1, the third gate insulation layer GIL3, and the second interlayer insulation layer ILD2 in a cross-sectional view.

At least one dam DAM may be formed on the first gate insulation layer GIL1, the second gate insulation layer GIL2, the first interlayer insulation layer ILD1, the third gate insulation layer GIL3, and the second interlayer insulation layer ILD2. The dam DAM may surround the hole MH in the second hole area HA2. The dam DAM may prevent the second encapsulation layer TFE2 from spreading into the first hole area HA1. For example, the second encapsulation layer TFE2 may disposed in an outside of the dam DAM with respect to the hole MH.

The dam DAM may have a structure in which multiple layers including an organic material are stacked. For example, the dam DAM may include the first via insulation layer, the second via insulation layer, and the pixel define layer (e.g., the first via insulation layer VIA1, the second via insulation layer VIA2, and the pixel define layer PDL of FIG. 4) may have a stacked structure.

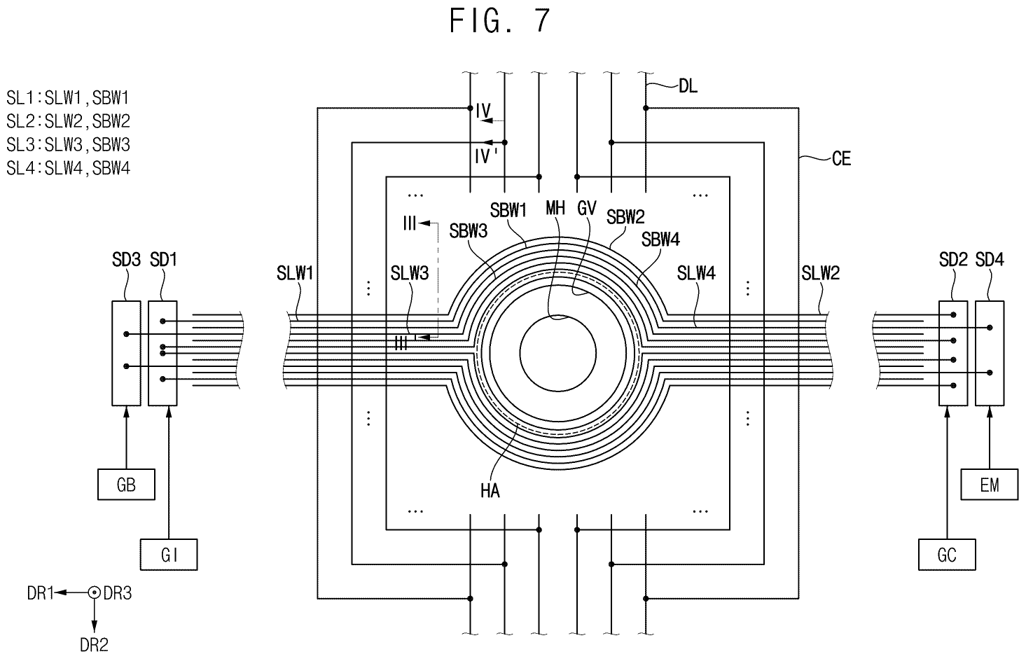

FIG. 6 is a plan view illustrating a display panel of FIG. 1. FIG. 7 is a plan view illustrating an example of lines passing a hole area of FIG. 6 and scan drivers connected to the lines.

Referring to FIGS. 6 and 7, the display panel DP may include a bending area BA which is bent, a peripheral area SA between the display area DA and the bending area BA, and the pad area PA.

The display panel DP includes the data driver DDV, the data line DL, a connection electrode CE, the pad portion PD, a first scan line SL1, a second scan line SL2, a third scan line SL3, and a fourth scan line SL4, the first scan driver SD1, the second scan driver SD2, a third scan driver SD3, and a fourth scan drivers SD4.

The data driver DDV and the pad portion PD may be disposed in the pad area PA. The data line DL may be electrically connected to the data driver DDV. The data line DL may receive the data voltage from the data driver DDV and apply the data voltage to the pixel PX. The pad portion PD may provide the first power voltage (e.g., the first power voltage ELVDD of FIG. 2) to the pixel PX through a driving voltage line.

The data line DL may be disposed on the display area DA. The data line may be disposed parallel to the second direction DR2 in the display area DA.

The data line DL may extend from the data driver DDV in a direction opposite to the second direction DR2. A plurality of data lines DL may be arranged. The plurality of data lines DL may be spaced apart from each other in the first direction DR1. The data line DL may apply a data signal transmitted from the data driver DDV to the pixel PX.

The data line DL located around the hole area HA may be disconnected by the hole area HA. Specifically, the data line DL extending from the data driver DDV may be disconnected at a point in the display area DA adjacent to the hole area HA in the second direction DR2. In addition, the data line DL extending from one side of the display area DA opposite to the data driver DDV in the second direction DR2 may be disconnected at a point in the display area DA adjacent to the hole area in the direction opposite to the second direction DR2.

The data line DL may be disposed on the first via insulation layer (e.g., the first via insulation layer VIA1 of FIG. 4). For example, the data line DL may be disposed on a same layer as the contact electrode (e.g., the contact electrode CTE of FIG. 4). However, the present disclosure may not be limited to this, and the data line DL may have various arrangements on the first via insulation layer.

The connection electrode CE may be disposed in the display area DA around the hole area HA. That is, the connection electrode CE may not be disposed in the hole area HA. The connection electrode CE may be electrically connected to a disconnected data line DL passing around the hole area HA. The connection electrode CE may bypass around the hole area HA. For example, the connection electrode CE may have a rectangular planar shape that bypasses the hole area HA. However, the present disclosure may not be limited to this.

The connection electrode CE may electrically connect the data line DL that is disconnected by the hole area HA. The connection electrode CE may contact each of a disconnected data line DL in the display area DA adjacent to the hole area HA in the second direction DR2 and a disconnected data line DL in the display area DA adjacent to the hole area HA in the direction opposite to the second direction DR2. Accordingly, the connection electrode CE may connect the disconnected data line DL and apply the data signal to the pixel PX disposed in the display area DA around the hole area HA.

The first, second, third, and fourth scan drivers SD1, SD2, SD3, and SD4 may be disposed in the non-display area NDA. For example, the first scan driver SD1 may be adjacent to one side, e.g., a first side, of the display area DA, and be disposed in the non-display area NDA. The second scan driver SD2 may be adjacent to an other side, e.g., a second side, opposite to the first side in the first direction DR1 of the display area DA, and be disposed in the non-display area NDA. The third scan driver SD3 may be adjacent to the one side, e.g., the first side, of the display area DA, and be disposed in the non-display area NDA. The fourth scan driver SD4 may be adjacent to the other side, e.g., the second side, of the display area DA, and be disposed in the non-display area NDA. However, the present disclosure may not be limited to this, and the first, second, third, and fourth scan drivers SD1, SD2, SD3, and SD4 may be disposed in the display area DA.

Different scan signals may be applied to the first, second, third, and fourth scan drivers SD1, SD2, SD3, and SD4. For example, the first gate initialization signal GI may be applied to the first scan driver SD1. The gate compensate signal GC may be applied to the second scan driver SD2. The second gate initialization signal GB may be applied to the third scan driver SD3. The light emission control signal EM may be applied to the fourth scan driver SD4. However, the present disclosure may not be limited to this, one scan signal selected among the first gate initialization signal GI, the gate compensate signal GC, the second gate initialization signal GB, and the light emission control signal EM may be applied to each of the first, second, third, and fourth scan drivers SD1, SD2, SD3, and SD4. In this case, a same signal may not be applied two different scan drivers among the first, second, third, and fourth scan drivers SD1, SD2, SD3, and SD4.

Each of the first, second, third, and fourth scan drivers SD1, SD2, SD3, and SD4 may be a one-side driving scan driver driven which is disposed in one side of the display device (e.g., the display device DD). That is, the first, second, third, and fourth scan drivers SD1, SD2, SD3, and SD4 may not be a scan driver driven on two side which is disposed in two sides of the display device.

However, the one-side driving scan driver may be defined as a scan driver which drives in such a way that a same signal as a scan signal (e.g., the first gate initialization signal GI, the gate compensate signal GC, the second gate initialization signal GB, and the light emission control signal EM) applied to the scan driver disposed on the one side of the display device is not applied to the driver disposed on the other side opposite to the one side. That is, the one-side driving may be referred as a driving in a manner in which one type of scan signal is applied to only one scan driver among a scan driver disposed on the one side of the display device and a scan driver disposed on the another side.

Unlike the one-side driving, a both-side driving may mean a driving in which same signal as the scan signal applied to the scan driver disposed on the one side of the display device is applied to the scan driver disposed on the other side. That is, the both-side driving may mean a method in which one type of scan signal is simultaneously applied to a scan driver disposed on the one side of the display device and a scan driver disposed on the other side.

A first scan line SL1, a second scan line SL2, a third scan line SL3, and a fourth scan line SL4 may be disposed in the display area DA. The first, second, third, and fourth scan lines SL1, SL2, SL3, and SL4 may be disposed parallel to the first direction DR1 in the display area DA.

The first scan line SL1 may be electrically connected to the first scan driver SD1. Accordingly, the first scan line SL1 may apply the scan signal applied to the first scan driver SD1 to the pixel PX. For example, the first scan line SL1 may apply the first gate initialization signal GI to the pixel PX.

The first scan line SL1 may extend in a direction opposite to the first direction DR1 from a portion connected to the first scan driver SD1 and may be disconnected in an area adjacent to the second scan driver SD2.

The second scan line SL2 may be electrically connected to the second scan driver SD2. Accordingly, the second scan line SL2 may apply the scan signal applied to the second scan driver SD2 to the pixel PX. For example, the second scan line SL2 may apply the gate compensation signal GC to the pixel PX.

The second scan line SL2 may extend in the first direction DR1 from a portion connected to the second scan driver SD2 and may be disconnected in an area adjacent to the first scan driver SD1.

The third scan line SL3 may be electrically connected to the third scan driver SD3. Accordingly, the third scan line SL3 may apply the scan signal applied to the third scan driver SD3 to the pixel PX. For example, the third scan line SL3 may apply the second gate initialization signal GB to the pixel PX.

The third scan line SL3 may extend in the direction opposite to the first direction DR1 from a portion connected to the third scan driver SD3 and may be disconnected at an area adjacent to the second scan driver SD2 and the fourth scan driver SD4.

The fourth scan line SL4 may be electrically connected to the fourth scan driver SD4. Accordingly, the fourth scan line SL4 may apply the scan signal applied to the fourth scan driver SD4 to the pixel PX. For example, the fourth scan line SL4 may apply the light emission control signal EM to the pixel PX.

The fourth scan line SLA extends in the first direction DR1 from a portion connected to the fourth scan driver SD4 and may be disconnected in an area adjacent to the first scan driver SD1 and the third scan driver SD3.

The first scan line SL1 adjacent to the hole area HA may include a first straight line SLW1 and a first bypass line SBW1. The second scan line SL2 adjacent to the hole area HA may include a second straight line SLW2 and a second bypass line SBW2. The third scan line SL3 adjacent to the hole area HA may include a third straight line SLW3 and a third bypass line SBW3. The fourth scan line SL4 adjacent to the hole area HA may include a fourth straight line SLW4 and a fourth bypass line SBW4.

Each of the first, second, third, and fourth straight lines SLW1, SLW2, SLW3, and SLW4 may be parallel to the first direction DR1. Each of the first, second, third, and fourth bypass lines SBW1, SBW2, SBW3, and SBW4 may have a shape corresponding to the boundary of the hole area HA, and may bypass along the boundary of the hole area HA.

Each of the first, second, third, and fourth scan lines SL1, SL2, SL3, SL4 may be spaced apart from each other in a plan view. Each of the first, second, third, and fourth straight lines SLW1, SLW2, SLW3, SLW4 may be spaced apart from each other in a second direction DR2. Each of the first, second, third, and fourth bypass lines SBW1, SBW2, SBW3, and SBW4 may be spaced apart from each other in a direction away from a center of the hole MH.

In an embodiment, each of the first, second, third, and fourth straight lines SLW1, SLW2, SLW3, SLW4 may be arranged alternatively in the second direction DR2. Specifically, each of the first, second, third, and fourth straight lines SLW1, SLW2, SLW3, SLW4 may be repeatedly arranged in an order of the second straight line SLW2, the first straight line SLW1, the fourth straight line SLW4, and the third straight line SLW3 along the second direction DR2.

In an embodiment, each of the first, second, third, and fourth bypass lines SBW1, SBW2, SBW3, and SBW4 may be arranged alternatively along the direction away from the center of the hole MH. Specifically, the first, second, third, and fourth bypass lines SBW1, SBW2, SBW3, and SBW4 may be arranged repeatedly in an order of the second bypass line SBW2, the first bypass line SBW1, the fourth bypass line SBW4, and the third bypass line SBW3 along the direction away from the center of the hole MH.

In an embodiment, an average distance from the center of the hole MH to the first, second, third, and fourth bypass lines SBW1, SBW2, SBW3, and SBW4 may be smaller than an average distance from the center of the hole MH to the connection electrode CE. Specifically, the first, second, third, and fourth bypass lines SBW1, SBW2, SBW3, and SBW4 may be arranged along the boundary of the hole area HA, and may be adjacent to the boundary of the hole area HA. However, an average distance from the boundary of the hole MH to the connection CE may be relatively larger than an average distance from the boundary of the hole MH to the first, second, third, and the fourth bypass lines SBW1, SBW2, SBW3, and SBW4.

In an embodiment, the first straight line SLW1 may be formed integrally and be integral with the first bypass line SBW1. That is, the first straight line SLW1 and the first bypass line SBW1 may include a same material, and may be formed through a same process.

In an embodiment, the second straight line SLW2 may be formed integrally and be integral with the second bypass line SBW2. That is, the second straight line SLW2 and the second bypass line SBW2 may include a same material, and may be formed through a same process.

In an embodiment, the third straight line SLW3 may be formed integrally and be integral with the third bypass line SBW3. That is, the third straight line SLW3 and the third bypass line SBW3 may include a same material, and may be formed through a same process.

In an embodiment, the fourth straight line SLW4 may be formed integrally and be integral with the fourth bypass line SBW4. That is, the fourth straight line SLW4 and the fourth bypass line SBW4 may include a same material, and may be formed through a same process.

In an embodiment, the data line DL is in the display area DA, the light-emitting element (e.g., the light-emitting element EE) is disposed in an area where the data line DL intersects with the first, second, third fourth scan lines SL1, SL2, SL3, and SL4. In addition, in the display area DA adjacent to the hole area HA, the light-emitting element is disposed in an area where the connection electrode CE intersects with the first, second, third fourth scan lines SL1, SL2, SL3, and SL4.

As describe above, the data line DL disconnected in display area DA adjacent to the hole area HA may be electrically connected through the connection electrode CE. Accordingly, the first, second, third, and fourth scan drivers SD1, SD2, SD3, and SD4 may be one-side driving scan drivers disposed in the one side or the other side of the display area DA. The first, second, third, and fourth scan lines SL1, SL2, SL3, and SL4, electrically connected to the first, second, third, and fourth scan drivers SD1, SD2, SD3, and SD4 respectively, may include first, second, third, and fourth bypass lines SBW1, SBW2, SBW3, and SBW4 respectively bypassing the hole area HA. Accordingly, a dead space of the display device may be reduced, and a size of the display area DA where the pixel PX emits light may increase.

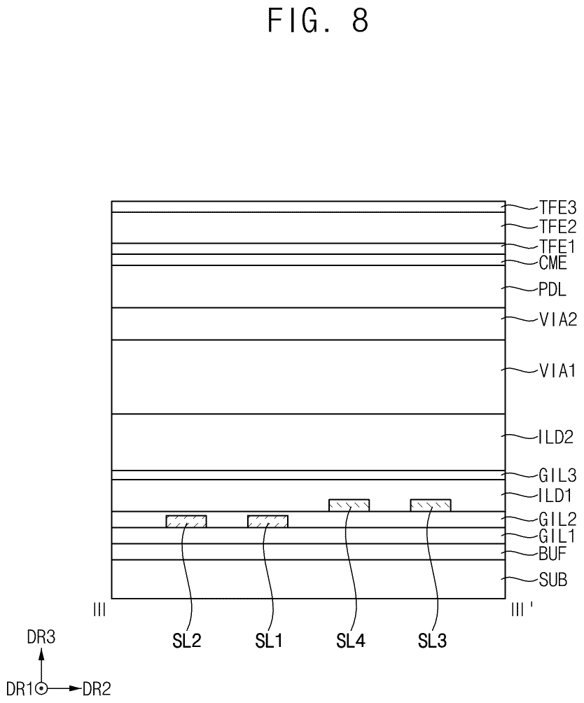

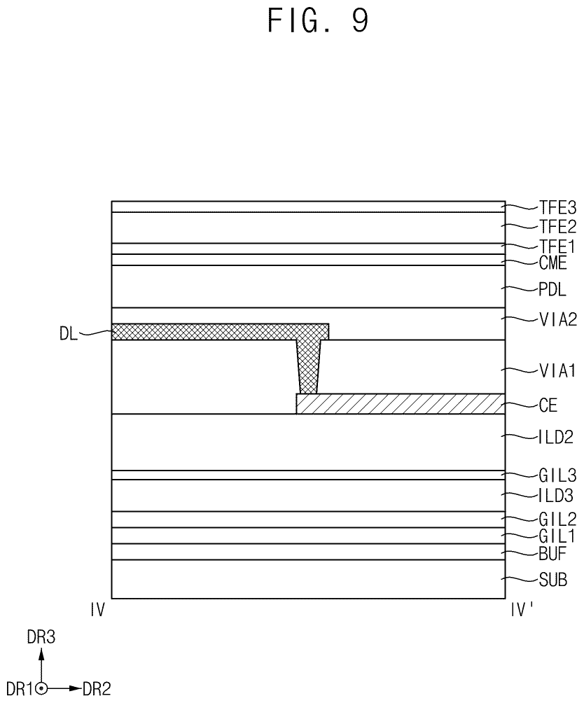

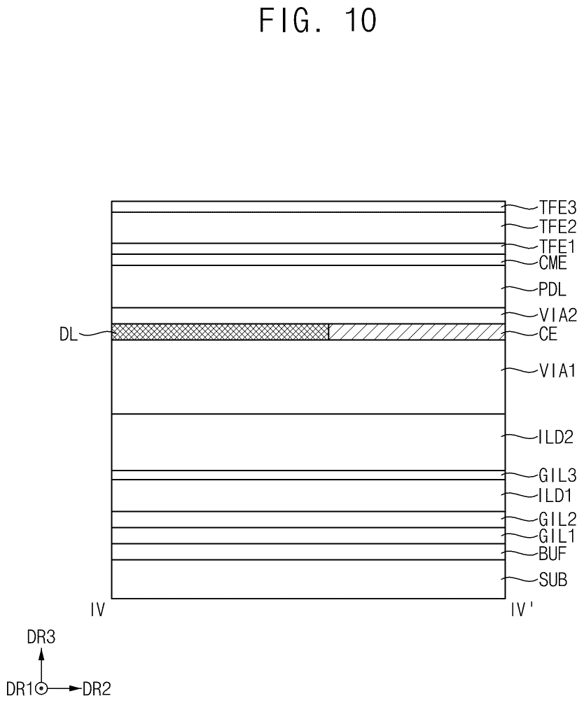

FIG. 8 is a cross-sectional view illustrating a cross-section taken along line III-III′ of FIG. 7. FIG. 9 is a cross-sectional view illustrating an example of a cross-section taken along line IV-IV′ of FIG. 7. FIG. 10 is a cross-sectional view illustrating another example of a cross-section taken along line IV-IV′ of FIG. 7.

Referring to FIGS. 8, 9, and 10, in an embodiment, the first scan line SL1 and the second scan line SL2 may be disposed in a same layer. For example, the first scan line SL1 and the second scan line SL2 may be disposed on the first gate insulation layer GIL1. Specifically, the first can line SL1 and the second scan line SL2 may be disposed in a same layer as the first gate electrode (e.g., the first gate electrode GE1).

In an embodiment, the third scan line SL3 and the fourth scan line SLA may be disposed in a same layer. For example, the third scan line SL3 and the fourth scan line SLA may be disposed on the second gate insulation layer GIL2. Specifically, the third scan line SL3 and the fourth scan line SL4 may be disposed in a same layer as the second gate electrode (e.g., the second gate electrode GE2). The third scan line SL3 and the fourth scan line SLA may be disposed on the first scan line SL1 and the second scan line SL2.

However, interlayer arrangement structures of the first, second, third, and fourth scan lines SL1, SL2, SL3, and SLA may not be limited to this, and each of the first, second, third, and fourth scan lines SL1, SL2, SL3, and SL4 may have various interlayer arrangement structures between the first gate insulation layer GIL1 and the first via insulation layer VIA1. That is, each of the first, second, third, and fourth scan lines SL1, SL2, SL3, and SL4 may disposed in a same layer as one electrode among the first gate electrode GE1 and the second gate electrode GE2.

In an embodiment, for example as illustrated in FIG. 9, the connection electrode CE may disposed in a different layer from the data line DL. For example, the connection electrode CE may disposed under the data line DL. Specifically, the connection electrode CE may be disposed between the first via insulation layer VIA1 and the second interlayer insulation layer ILD2, and the data line DL may be disposed on the first via insulation layer VIA1. However, the present disclosure may not be limited to this, the connection electrode CE may be disposed on an upper portion of the data line DL. For example, the connection electrode CE may be disposed on the first via insulation layer VIA1, and the data line DL may be disposed between the first via insulation layer VIA1 and the second interlayer insulation layer ILD2.

When the connection electrode CE is disposed in a different layer from the data line DL, the connection electrode CE and the data line DL may be electrically connected to each other through a contact hole penetrating an insulation layer disposed between the connection electrode CE and the data line DL. For example, when the connection electrode CE may be disposed between the second interlayer insulation layer ILD2 and the first via insulation layer VIA1, and the data line DL may be disposed on the first via insulation layer VIA1, the data line DL may be electrically connected to the data line DL through a contact hole penetrating the first via insulation layer VIA1.

That is, each of the connection electrode CE and the data line DL may be disposed in a layer as an electrode among the first source electrode SE1 and the contact electrode CTE.

In an embodiment, for example as illustrated in FIG. 10, the connection electrode CE may be disposed in a same layer as the data line DL. For example, the connection electrode CE may be disposed between the first via insulation layer VIA1 and the second via insulation layer VIA2, and may be disposed in a same layer as the data line DL. However, the present disclosure may not be limited to this, the connection electrode CE and the data line DL may have various structures disposed between the second interlayer insulation layer ILD2 and the pixel define layer PDL.

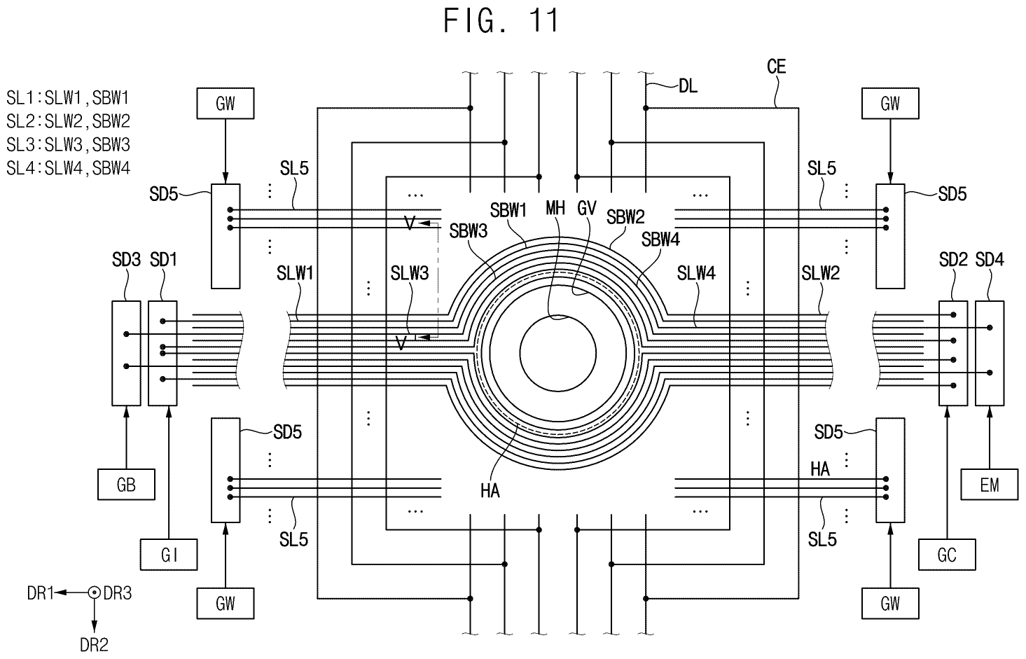

FIG. 11 is a plan view illustrating another example of lines passing a hole area of FIG. 6 and scan drivers connected to the lines.

The display device described with reference to FIG. 11 may be substantially the same as the display device described with reference to FIG. 7 except for fifth scan drivers SD5 and a fifth scan line SL5.

Hereinafter, descriptions that overlap with the components of the display device described with reference to FIG. 7 will be omitted or simplified.

Referring to FIG. 11, fifth scan drivers SD5 may be disposed on the opposite sides of the display area (e.g., the display area DA of FIG. 6). For example, at least one of the fifth scan drivers SD5 may be located in the non-display area (e.g. the non-display area NDA of FIG. 6) adjacent to the one side of the display area where the first and third scan drivers SD1 and SD3 are disposed and at least one of the fifth scan drivers SD5 may be located in the non-display area adjacent to the other side of the display area where the second scan driver SD2 and the fourth scan driver SD4 are disposed. That is, the fifth scan drivers SD5 may be both-side driving scan drivers. However, the present disclosure may not be limited to this, and the fifth scan drivers SD5 may be disposed in the display area DA.

A scan signal different from the scan signals applied to the first, second, third, and fourth scan drivers SD1, SD2, SD3, and SD4 may be applied to the fifth scan drivers SD5. For example, the gate write signal GW may be applied to the fifth scan drivers SD5.

The fifth scan lines SL5 may be electrically connected to the fifth scan drivers SD5. Accordingly, the fifth scan lines SL5 may apply the scan signal applied to the fifth scan drivers SD5 to the pixel PX. For example, the fifth scan lines SL5 may apply the gate write signal GW to the pixel PX.

The fifth scan lines SL5 may extend from the fifth scan drivers SD5 in the first direction DR1 or in the direction opposite to the first direction DR1. The fifth scan lines SL5 may be arranged in the second direction DR2. The fifth scan lines SL5 arranged in the second direction DR2 may be spaced apart from each other. In addition, the fifth scan lines SL5 may be spaced apart from the first, second, third, and fourth scan lines SL1, SL2, SL3, and SL4.

The fifth scan lines SL5 may be disconnected by the hole area HA. That is, the fifth scan lines SL5 may not include a bypass line that bypasses the hole area HA.

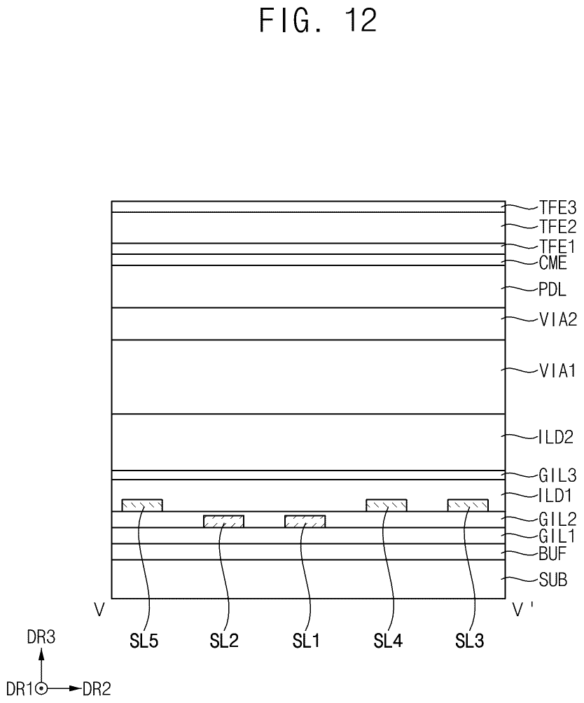

FIG. 12 is a cross-sectional view illustrating a cross-section taken along line V-V′ of FIG. 11.

The display device described with reference to FIG. 12 may be substantially the same as the display device described with reference to FIG. 8 except for the fifth scan drivers SD5 and the fifth scan line SL5.

Hereinafter, descriptions that overlap with the components of the display device described with reference to FIG. 8 will be omitted or simplified.

Referring to FIG. 12, the fifth scan line SL5 may be disposed between the second gate insulation layer GIL2 and the first interlayer insulation layer ILD1. For example, the fifth scan line SL5 may be disposed on a same layer as the second gate electrode. In addition, the fifth scan line SL5 may be disposed on a same layer as the third scan line SL3 and the fourth scan line SL4. However, the present disclosure may not be limited to this, and the fifth scan line SL5 may have various interlayer arrangement structures between the first gate insulation layer GIL1 and the first via insulation layer VIA1. That is, the fifth scan line SL5 may be disposed on a same layer as one electrode among the first and second gate electrodes GE1 and GE2 of FIG. 4.

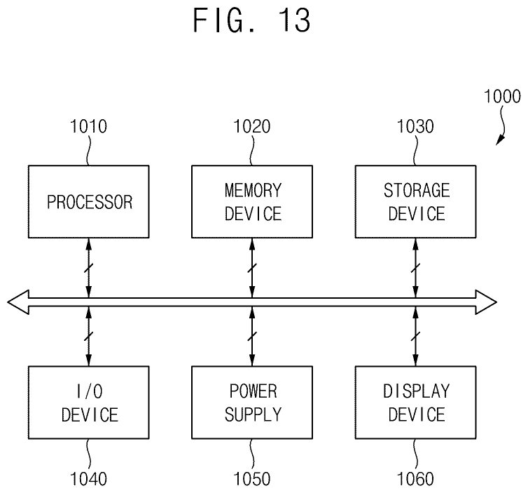

FIG. 13 is a block diagram illustrating an electronic device according to an embodiment.

Referring to FIG. 13, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device DD of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

The display device according to the embodiments may be applied to a electronic device included in a computer, a notebook, a mobile phone, a smartphone, a smart pad, a PMP, a PDA, an MP3 player, or the like.

Although the display device according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a substrate including a hole area defining a hole, a display area adjacent to the hole area, and a non-display area adjacent to the display area;
a first scan driver disposed on the substrate and adjacent to a first side of the display area;
a second scan driver disposed on the substrate, adjacent to a second side of the display area opposite to the first side of the display area, and to which a scan signal, different from a scan signal applied to the first scan driver, is applied;
a first scan line electrically connected to the first scan driver, spaced apart from the second scan driver, and including a first straight line extending from a portion connected to the first scan driver along a first direction and a first bypass line along a boundary of the hole area;
a second scan line electrically connected to the second scan driver, spaced apart from the first scan driver, and including a second straight line extending from a portion connected to the second scan driver along a direction opposite to the first direction and a second bypass line along the boundary of the hole area; and
a data line disposed on the substrate and extending along a second direction which intersects with the first direction.

2. The display device of claim 1, wherein the first scan driver is disconnected in an area adjacent to the second scan driver, and
the second scan driver is disconnected in an area adjacent to the first scan driver.

3. The display device of claim 1, further comprising:
a third scan driver disposed on the substrate and adjacent to the first scan driver;
a fourth scan driver disposed on the substrate and adjacent to the second scan driver;
a third scan line electrically connected to the third scan driver and including a third straight line extending from a portion connected to the third scan driver along the first direction and a third bypass line along the boundary of the hole area; and
a fourth scan line electrically connected to the fourth scan driver and including a fourth straight line extending from a portion connected to the fourth scan driver along the direction opposite to the first direction and a fourth bypass line along the boundary of the hole.

4. The display device of claim 3, wherein the third scan line is spaced apart from the second scan driver and the fourth scan driver, and
the fourth scan line is spaced apart from the first scan driver and third scan driver.

5. The display device of claim 3, wherein the first straight line and the first bypass line are integral,
the second straight line and the second bypass line are integral,
the third straight line and the third bypass line are integral, and
the fourth straight line and the fourth bypass line are integral.

6. The display device of claim 3, wherein each of the first scan line, the second scan line, the third scan line, and the fourth scan line are arranged alternatively along the second direction.

7. The display device of claim 3, wherein each of the first scan line, the second scan line, the third scan line, and the fourth scan line are arranged alternatively along a direction away from a center of the hole.

8. The display device of claim 3, further comprising:
a plurality of fifth scan drivers disposed on the first and second sides of the display area and spaced apart from each other in the first direction; and
a plurality of fifth scan lines electrically connected to the fifth scan driver.

9. The display device of claim 8, wherein the fifth scan drivers are disconnected by the hole.

10. The display device of claim 8, wherein different scan signals are applied to the first scan driver, the second scan driver, the third scan driver, the fourth scan driver, and the fifth scan driver.

11. The display device of claim 3, further comprising:
a connection electrode disposed in the display area on the substrate and electrically connected to the data line around the hole area.

12. The display device of claim 11, wherein an average distance from a center of the hole to the first scan line, the second scan line, the third scan line, and the fourth scan line is smaller than an average distance from the center of the hole to the connection electrode.

13. The display device of claim 11, wherein the data line is disposed in a same layer with the connection layer.

14. The display device of claim 11, wherein the data line is disposed in a different layer from the connection layer.

15. A display device comprising:
a substrate including a hole area defining a hole, a display area adjacent to the hole area, and a non-display area adjacent to the display area;
a first scan driver disposed on the substrate and adjacent to a first side of the display area;
a second scan driver disposed on the substrate, adjacent to a second side of the display area opposite to the first side of the display area, and to which a scan signal, different from a signal applied to the first scan driver, is applied;
a first scan line electrically connected to the first scan driver, extending from a portion connected to the first scan driver, and disconnected in an area adjacent to the second scan driver;
a second scan line electrically connected to the second scan driver, extending from a portion connected to the second scan driver and disconnected in an area adjacent to the first scan driver;
a data line disposed on the first scan line and the second scan line and extending along a second direction intersecting with the first direction; and
a connection electrode disposed on the first scan line and the second scan line, and electrically connected to the data line around the hole area.

16. The display device of claim 15, wherein the first scan line includes a first straight line parallel to the first direction and a first bypass line bypassing a boundary of the hole area, and
the second scan line includes a second straight line parallel to the first direction and a second bypass line bypassing the boundary of the hole area.

17. The display device of claim 16, wherein the first straight line and the second straight line are arranged alternatively along the second direction, and
the first bypass line and the second bypass line are arranged alternatively along a direction away from a center of the hole.

18. The display device of claim 16, wherein the first straight line and the first bypass line are integral, and
the second straight line and the second bypass line are integral.

19. The display device of claim 16, wherein different scan signals are applied to the first scan driver and the second scan driver.

20. The display device of claim 15, wherein the data line is disposed in a same layer with the connection electrode.

21. An electronic device comprising:
a display device; and
a power supply configured to provide power to the display device,
wherein the display device comprises:
a substrate including a hole area defining a hole, a display area adjacent to the hole area, and a non-display area adjacent to the display area;
a first scan driver disposed on the substrate and adjacent to a first side of the display area;
a second scan driver disposed on the substrate, adjacent to a second side of the display area opposite to the first side of the display area, and to which a scan signal, different from a scan signal applied to the first scan driver, is applied;
a first scan line electrically connected to the first scan driver, spaced apart from the second scan driver, and including a first straight line extending from a portion connected to the first scan driver along a first direction and a first bypass line along a boundary of the hole area;
a second scan line electrically connected to the second scan driver, spaced apart from the first scan driver, and including a second straight line extending from a portion connected to the second scan driver along a direction opposite to the first direction and a second bypass line along the boundary of the hole area; and
a data line disposed on the substrate and extending along a second direction which intersects with the first direction.
